(19) United States
(12) Patent Application Publication
(10) Pub. No.: US 2025/0212328 A1
(43) Pub. Date: Jun. 26, 2025

(54) WIRING CIRCUIT BOARD AND METHOD OF PRODUCING THE WIRING CIRCUIT BOARD

(71) Applicant: NITTO DENKO CORPORATION, Osaka (JP)

(72) Inventors: Takaya KOUCHI, Osaka (JP); Shusaku SHIBATA, Osaka (JP)

(73) Assignee: NITTO DENKO CORPORATION, Osaka (JP)

(21) Appl. No.: 18/985,998

(22) Filed: Dec. 18, 2024

(30) Foreign Application Priority Data
Dec. 25, 2023 (JP) 2023-218679

(51) Int. Cl. H05K 1/11

(52) U.S. Cl. CPC H05K 1/11; H05K 2201/10227

(57) ABSTRACT

A wiring circuit board includes a terminal disposition portion in which a terminal is disposed, and a wiring portion in which a wire is disposed. A ratio (T1/W1) of a thickness T1 of a metal supporting layer of the wiring portion to a width W1 of the metal supporting layer of the wiring portion is 2 or more. The wire has a central portion and an end portion in the width direction of the wiring portion. The central portion protrudes toward the opposite side to the metal supporting layer with respect to a first insulating layer in the thickness direction as compared with the end portion.

### CROSS-REFERENCE TO RELATED APPLICATION

The present application claims priority from Japanese Patent Application No. 2023-218679 filed on Dec. 25, 2023, the content of which is hereby incorporated by reference into this application.

### TECHNICAL FIELD

The present invention relates to a wiring circuit board and a method of producing the wiring circuit board.

### BACKGROUND ART

There has been a conventionally known wiring circuit board including a plurality of wiring portions arranged at intervals from each other (for example, see Patent document 1 below).

In this wiring circuit board, the thickness of the wiring portion is larger than (more than twice) the width of the wiring portion. Therefore, the wiring portion can easily be moved in the width direction as compared with in the thickness direction.

### CITATION LIST

### Patent Document

Patent Document 1: Japanese Unexamined Patent Publication No. 2019-212656

### SUMMARY OF THE INVENTION

### Problem to be Solved by the Invention

In the wiring circuit board as described in Patent Document 1, in order not to hinder the movement of the wiring portion in the width direction, it may be desired to increase the stiffness of the wiring portion in the thickness direction.

The present invention provides a wiring circuit board that can increase the stiffness of the wiring portion in the thickness direction so as not to hinder the movement of the wiring portion in the width direction, and a method of producing the wiring circuit board.

### Means for Solving the Problem

The present invention [1] includes a wiring circuit board having a terminal disposition portion in which a terminal is disposed, and a wiring portion in which a wire connected to the terminal is disposed, the wiring circuit board including: a metal supporting layer; an insulating layer disposed on the metal supporting layer in a thickness direction of the metal supporting layer; and a conductive pattern disposed on the insulating layer in the thickness direction, and the conductive pattern having the terminal and the wire connected to the terminal, wherein a ratio of a thickness of the metal supporting layer of the wiring portion to a width of the metal supporting layer of the wiring portion is 2 or more, wherein the wire has a central portion and an end portion in a width direction of the wiring portion, and wherein the central portion protrudes toward an opposite side to the metal supporting layer with respect to the insulating layer in the thickness direction as compared with the end portion.

According to such a configuration, the ratio of the thickness of the metal supporting layer of the wiring portion is 2 or more with respect to the width of the metal supporting layer of the wiring portion. Therefore, the wiring portion can easily be moved in the width direction as compared with in the thickness direction.

Then, the central portion of the wire protrudes toward the opposite side to the metal supporting layer with respect to the insulating layer in the thickness direction as compared with the end portion.

Therefore, it is possible to increase the stiffness of the wire in the thickness direction while suppressing the increase in the stiffness of the wire in the width direction.

As a result, in order not to hinder the movement of the wiring portion in the width direction, it is possible to increase the stiffness of the wiring portion in the thickness direction.

The present invention [2] includes the wiring circuit board described in the above-described [1], wherein a ratio of a thickness of the central portion to a width of the wire is 2 or less.

According to such a configuration, it is possible to suppress an excessive increase in the stiffness of the wire in the thickness direction.

The present invention [3] includes the wiring circuit board described in the above-described [1] or [2], wherein a difference between the thickness of the central portion and a thickness of the end portion is 10% or more of the thickness of the central portion.

According to such a configuration, the stiffness of the wire in the thickness direction can reliably be increased.

The present invention [4] includes the wiring circuit board described in the above-described [1] or [3], wherein the wire including: a first conductor layer disposed on the insulating layer in the thickness direction, the first conductor layer disposed in the central portion of the wire in the width direction, and the first conductor layer having a first width; and a second conductor layer disposed on the insulating layer in the thickness direction, the second conductor layer having a second width larger than the first width, and the second conductor layer covering the first conductor layer.

According to such a configuration, with a simple structure in which the second conductor layer covers the first conductor layer, a wire in which the central portion protrudes as compared to the end portion can be formed.

The present invention [5] includes a method of producing the wiring circuit board described in the above-described [4], the method including: an insulating layer formation step of forming the insulating layer on the metal supporting layer; a first conductor layer formation step of forming the first conductor layer on the insulating layer; and a second conductor layer formation step of forming the second conductor layer on the insulating layer.

According to such a method, with a simple method in which the second conductor layer covers the first conductor layer, a wire in which the central portion protrudes as compared to the end portion can be formed.

### Effects of the Invention

According to the wiring circuit board of the present invention and the method of producing the wiring circuit board, it is possible to increase the stiffness of the wiring portion in the thickness direction so as not to hinder the movement of the wiring portion in the width direction.

### BRIEF DESCRIPTION OF THE DRAWINGS

FIG. 1 is a plan view of a wiring circuit board as one embodiment of the present invention.

FIG. 2 is a cross-sectional view of the wiring circuit board shown in FIG. 1, taken along line A-A.

FIG. 3 is a back-side view of the wiring circuit board as one embodiment of the present invention.

FIG. 4 is a cross-sectional view of the wiring circuit board shown in FIG. 1, taken along line B-B.

FIGS. 5A and 5B are views of steps for explaining the method of producing the wiring circuit board. FIG. 5A shows a step of forming a first insulating layer. FIG. 5B shows a step of forming a first conductor layer.

Following FIG. 5B, FIGS. 6A and 6B are views of steps for explaining the method of producing the wiring circuit board. FIG. 6A shows a step of forming a second conductor layer.

FIG. 6B shows a step of forming a second insulating layer.

FIG. 7 shows a wiring circuit board of the variation (3).

FIG. 8 shows a wiring circuit board of the variation (4).

FIG. 9A is a cross-sectional view of the simulation model produced in Example 1. FIG. 9B is a cross-sectional view of the simulation model produced in Comparative Example 1. FIG. 9C is a cross-sectional view of the simulation model produced in Comparative Example 2.

FIG. 10A is a cross-sectional view of the simulation model produced in Example 2.

FIG. 10B is a cross-sectional view of the simulation model produced in Example 3.

FIG. 11A is a cross-sectional view of the simulation model produced in Example 4.

FIG. 11B is a cross-sectional view of the simulation model produced in Example 5.

### DESCRIPTION OF THE EMBODIMENT

### 1. Wiring Circuit Board

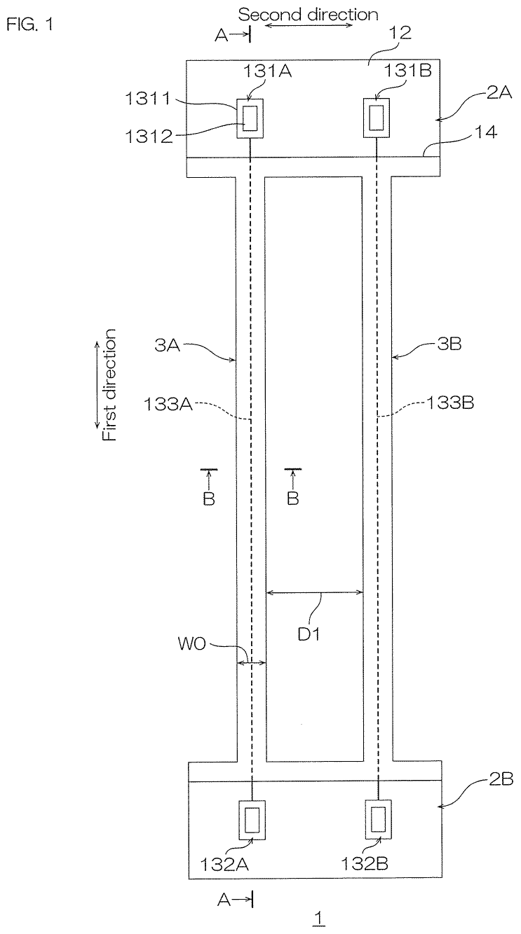

Referring to FIGS. 1 to 3, a wiring circuit board 1 is described.

As shown in FIG. 1, the wiring circuit board 1 has two terminal disposition portions 2A and 2B, and a plurality of wiring portions 3A and 3B. The terminal disposition portions 2A and 2B are spaced from each other in a first direction. The first direction is perpendicular to a thickness direction of the wiring circuit board 1. Each of the terminal disposition portions 2A and 2B extends in a second direction. The second direction is perpendicular to both of the first direction and the thickness direction. In the terminal disposition portion 2A, terminals 131A and 131B of a conductive pattern 13 described later are disposed. In the terminal disposition portion 2B, terminals 132A and 132B of a conductive pattern 13 described later are disposed.

The wiring portions 3A and 3B are disposed between the terminal disposition portion 2A and the terminal disposition portion 2B in the first direction. In the present embodiment, each of the wire portions 3A and 3B extends in the first direction. One end portion of each of the wiring portions 3A and 3B in the first direction is connected to the terminal disposition portion 2A. The other end portion of each of the wiring portions 3A and 3B in the first direction is connected to the terminal disposition portion 2B. The shape of each of the wiring portions 3A and 3B is not limited. Each of the wiring portions 3A and 3B may have a linear shape or be curved. The wiring portions 3A and 3B are arranged in the second direction. In other words, the wiring portions 3A and 3B are arranged in a direction perpendicular to the direction in which the wiring portion 3A extends. The wiring portions 3A and 3B are spaced from each other in the second direction. In other words, the wiring portions 3A and 3B are spaced from each other in a direction perpendicular to the direction in which the wiring portion 3A extends. In the wiring portion 3A, a wire 133A of the conductive pattern 13 described later is disposed. In the wiring portion 3B, a wire 133B of the conductive pattern 13 described later is disposed.

A width W0 of the wiring portion 3A is, for example, 10 μm to 300 μm, preferably 50 μm to 250 μm.

The “width” is the maximum length in a direction perpendicular to both of the direction in which the wiring portion extends and the thickness direction. For example, the “width” of the wiring portion 3A is the maximum length in a direction perpendicular to both of the direction in which the wiring portion 3A extends and the thickness direction. In the present embodiment, the “width” is the maximum length in the second direction.

An interval D1 between the wiring portion 3A and the wiring portion 3B is, for example, 5 μm to 300 μm, preferably 10 μm to 250 μm.

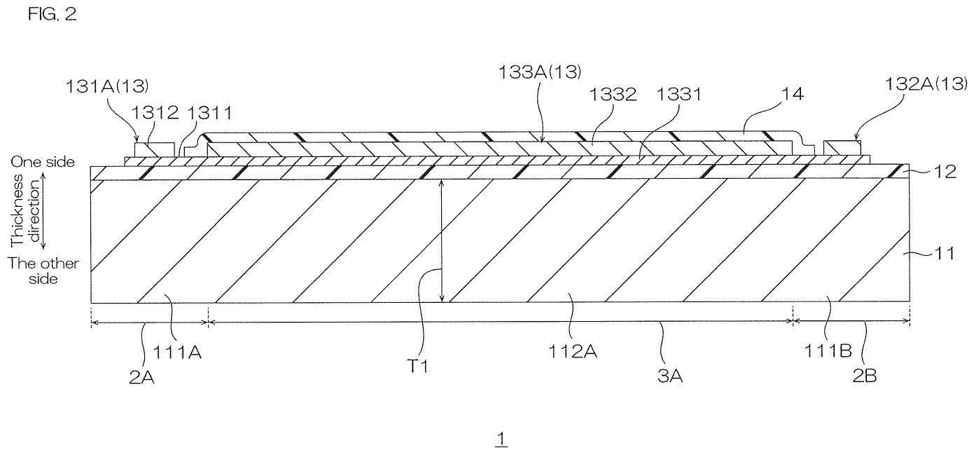

As shown in FIG. 2, the wiring circuit board 1 includes a metal supporting layer 11, a first insulating layer 12 as an example of an insulating layer, a conductive pattern 13, and a second insulating layer 14.

### (1) Metal Supporting Layer

The metal supporting layer 11 supports the first insulating layer 12, the conductive pattern 13, and the second insulating layer 14. The metal supporting layer 11 is made of metal. Examples of the material of the metal supporting layer 11 include, for example, copper, nickel, cobalt, iron, and the alloys thereof. Examples of the alloy include a copper alloy. As the material of the metal supporting layer 11, preferably, a copper alloy is used.

A thickness T1 of the metal supporting layer 11 is, for example, 10 μm to 300 μm, and preferably 50 μm to 250 μm.

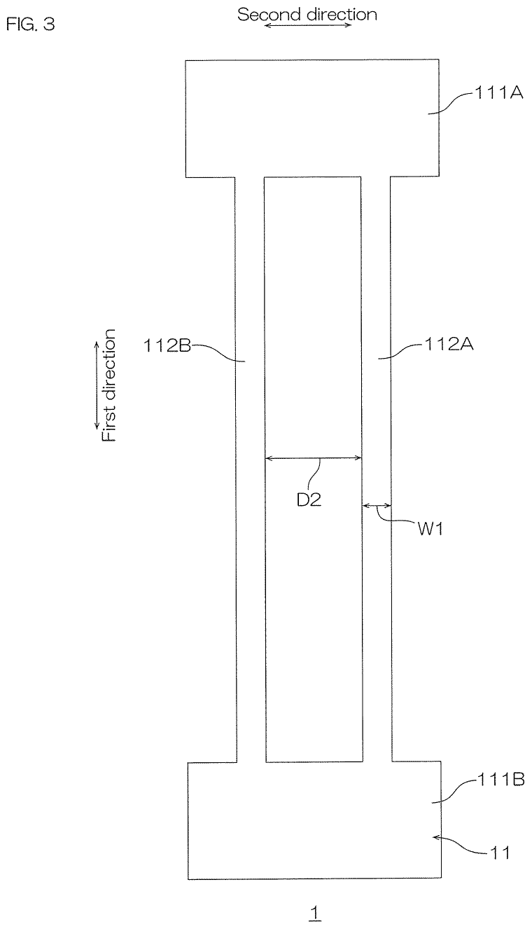

As shown in FIG. 3, the metal supporting layer 11 has two terminal supporting portions 111A and 111B and a plurality of wire supporting portions 112A and 112B.

The terminal supporting portion 111A is the metal supporting layer 11 of the terminal disposition portion 2A (see FIG. 1). The terminal supporting portion 111A supports at least the terminals 131A and 131B of the conductive pattern 13. The terminal supporting portion 111A may support a part of each of the wires 133A and 133B of the conductive pattern 13.

The terminal supporting portion 111B is the metal supporting layer 11 of the terminal disposition portion 2B (see FIG. 1). The terminal supporting portion 111B is spaced apart from the terminal supporting portion 111A in the first direction. The terminal supporting portion 111B supports at least the terminals 132A and 132B of the conductive pattern 13. The terminal supporting portion 111B may support a part of each of the wires 133A and 133B of the conductive pattern 13.

The wire supporting portion 112A is the metal supporting layer 11 of the wiring portion 3A (see FIG. 1). The wire supporting portion 112A is disposed between the terminal supporting portion 111A and the terminal supporting portion 111B in the first direction. The wire supporting portion 112A supports the wire 133A (see FIG. 1). The wire supporting portion 112A extends along the wire 133A in the first direction. One end portion of the wire supporting portion 112A in the first direction is connected to the terminal supporting portion 111A. The other end portion of the wire supporting portion 112A in the first direction is connected to the terminal supporting portion 111B.

The wire supporting portion 112B is the metal supporting layer 11 of the wiring portion 3B (see FIG. 1). The wire supporting portion 112B is disposed between the terminal supporting portion 111A and the terminal supporting portion 111B in the first direction. The wire supporting portion 112B supports the wire 133B (see FIG. 1). The wire supporting portion 112B extends along the wire 133B in the first direction. One end portion of the wire supporting portion 112B in the first direction is connected to the terminal supporting portion 111A. The other end portion of the wire supporting portion 112B in the first direction is connected to the terminal supporting portion 111B. The wire supporting portions 112A and 112B are arranged in the second direction. The wire supporting portions 112A and 112B are spaced from each other in the second direction.

A width W1 of the wire supporting portion 112A is, for example, 5 μm to 300 μm, preferably 10 μm to 250 μm. The width W1 of the wire supporting portion 112A may be the same as or different from the width W0 of the wiring portion 3A (see FIG. 1).

With respect to the width W1 of the wire supporting portion 112A, the ratio (T1/W1) of the thickness T1 of the wire supporting portion 112A is 2 or more, preferably 5 or more. Hereinafter, the ratio (T1/W1) is defined as the aspect ratio of the wire supporting portion 112A.

When the aspect ratio (T1/W1) of the wire supporting portion 112A is the lower limit or more, it is possible to secure the stiffness of the wiring portion 3A in the thickness.

The aspect ratio (T1/W1) of the wire supporting portion 112A is, for example, 30 or less, preferably 10 or less.

The aspect-ratio (T1/W1) of the wire supporting portion 112A may be 2 to 30 or 5 to 10.

The interval D2 between the wire supporting portion 112A and the wire supporting portion 112B is, for example, 5 μm to 300 μm, preferably 10 μm to 250 μm. The interval D2 may be the same as or different from the interval D1.

### (2) First Insulating Layer

As shown in FIG. 2, the first insulating layer 12 is disposed at one side of the metal supporting layer 11 in the thickness direction of the metal supporting layer 11. The first insulating layer 12 is disposed on one surface of the metal supporting layer 11 in the thickness direction. The first insulating layer 12 is disposed between the metal supporting layer 11 and the conductive pattern 13 in the thickness direction. The first insulating layer 12 insulates the metal supporting layer 11 from the conductive pattern 13. The first insulating layer 12 is made of resin. Examples of the resin include polyimide, maleimide, epoxy resin, polybenzoxazole, and polyester.

### (3) Conductive Pattern

The conductive pattern 13 is disposed at one side of the first insulating layer 12 in the thickness direction. The conductive pattern 13 is disposed on one surface of the first insulating layer 12 in the thickness direction. The conductive pattern 13 is disposed on the opposite side to the metal supporting layer 11 with respect to the first insulating layer 12 in the thickness direction. The shape of the conductive pattern 13 is not limited.

As shown in FIG. 1, the conductive pattern 13 has a plurality of terminals 131A and 131B, a plurality of terminals 132A and 132B, and a plurality of wires 133A and 133B.

The terminals 131A and 131B are disposed in the terminal disposition portion 2A. Each of the terminals 131A and 131B has a square land shape. The terminals 131A and 131B are arranged in the second direction. The terminals 131A and 131B are spaced from each other in the second direction.

The terminals 132A and 132B are disposed in the terminal disposition portion 2B. Each of the terminals 132A and 132B has a square land shape. The terminals 132A and 132B are arranged in the second direction. The terminals 132A and 132B are spaced from each other in the second direction.

Each of the terminals 131A, 131B, 132A, and 132B has a first conductor layer 1311 and a second conductor layer 1312.

The first conductor layer 1311 is disposed on the first insulating layer 12 in the thickness direction. The first conductor layer 1311 is made of metal. Examples of the metal include, for example, copper, silver, gold, iron, aluminum, chromium, and the alloys thereof. To obtain good electrical properties, preferably, copper is used as the metal.

The second conductor layer 1312 is disposed on the first conductor layer 1311 in the thickness direction. The second conductor layer 1312 is made of metal. Examples of the metal include the same metals as those of the first conductor layer 1311. The second conductor layer 1312 is preferably made of the same metal as that of the first conductor layer 1311.

The wire 133A electrically connects the terminal 131A and the terminal 132A. One end portion of the wire 133A is connected to the terminal 131A. The other end portion of the wire 133A is connected to the terminal 132A. At least a part of the wire 133A is disposed in the wiring portion 3A.

The wire 133B electrically connects the terminal 131B and the terminal 132B. One end portion of the wire 133B is connected to the terminal 131B. The other end portion of the wire 133B is connected to the terminal 132B. At least a part of the wire 133B is disposed in the wiring portion 3B. The wires 133A and 133B are arranged in the second direction. The wires 133A and 133B are spaced from each other in the second direction.

### (6) Second Insulating Layer

As shown in FIG. 2, the second insulating layer 14 covers the entire of the wires 133A and 133B. The second insulating layer 14 is disposed on the first insulating layer 12 in the thickness direction. As shown in FIGS. 1 and 2, the second insulating layer 14 does not cover the terminals 131A, 131B, 132A, and 132B. The second insulating layer 14 is made of resin. Examples of the resin include polyimide, maleimide, epoxy resin, polybenzoxazole, and polyester.

### 2. Details of Wire

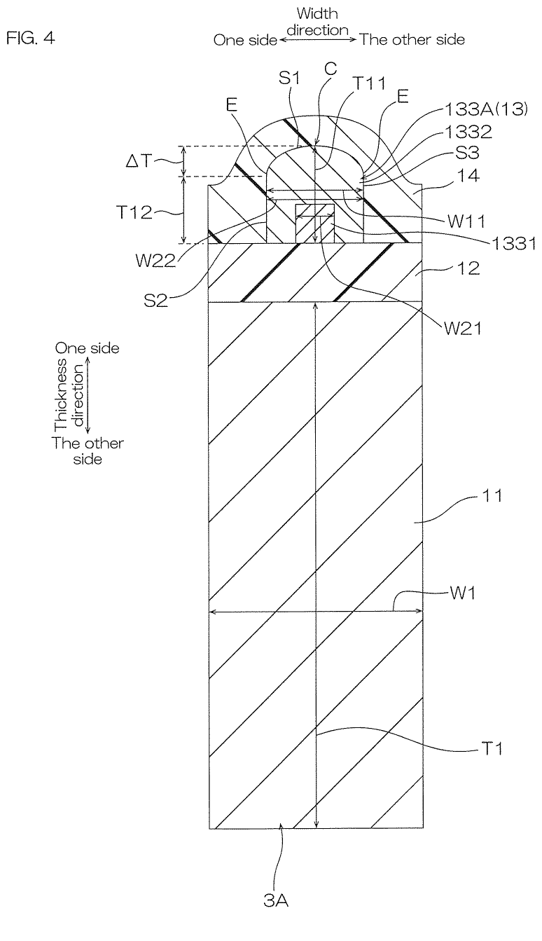

Referring to FIG. 4, details of the wire 133A are described. The wire 133B has the same structure as the wire 133A. Descriptions of the wire 133B is omitted.

As shown in FIG. 4, the wire 133A has an arched shape in the cross-sectional view. The wire 133A has a central portion C and an end portion E in a width direction of the wire supporting portion 112A. The central portion C is disposed at the center of the wire 133A in the width direction. The central portion C protrudes toward one side in the thickness direction as compared with the end portion E. In other words, as compared with the end portion E, the central portion C protrudes toward the opposite side to the metal supporting layer 11 with respect to the first insulating layer 12 in the thickness direction. One end surface S1 of the wire 133A in the thickness direction has an approximately circular arc shape. Both side surfaces S2 and S3 of the wire 133A in the width direction are planes extending in the thickness direction.

With respect to a width W11 of the wire 133A, the ratio (T11/W11) of a thickness T11 of the central portion C is, for example, 3.0 or less, preferably 2.0 or less, more preferably 1.7 or less, more preferably 1.3 or less. Hereinafter, the ratio (T11/W11) is defined as the aspect ratio of the wire 133A.

When the aspect ratio of the wire 133A is the above-mentioned upper limit or less, an excessive increase in the stiffness of the wire 133A in the thickness direction can be suppressed.

The aspect ratio of the wire 133A is, for example, 0.1 or more, preferably 0.3 or more, more preferably 0.5 or more, and more preferably 0.8 or more.

When the aspect ratio of the wire 133A is the above-mentioned lower limit or more, the stiffness of the wire 133A in the thickness direction can be increased with respect to the stiffness of the wire 133A in the width direction.

The aspect ratio of the wire 133A may be 0.1 to 3.0, 0.3 to 2.0, 0.5 to 1.7, or 0.8 to 1.3. The difference ΔT between the thickness T11 of the central portion C and a thickness T12 of the end portion E is, for example, 10% or more of the thickness T11 of the central portion C, preferably 20% or more, more preferably 25% or more.

The percentage of “the difference ΔT between the thickness T11 of the central portion C and the thickness T12 of the end portion E” to the thickness T11 of the central portion C is defined as the protrusion rate of the central portion C.

When the protrusion rate of the central portion C is the above-mentioned lower limit or more, the stiffness of the wire in the thickness direction can reliably be increased.

The protrusion rate of the central portion C is, for example, 70% or less, preferably 60% or less, more preferably 55% or less.

When the protrusion rate of the central portion C is the above-mentioned upper limit or less, it is possible to secure the cross-sectional area of the wire and reduce the electrical resistance of the wire.

The protrusion rate of the central portion C may be 10% to 70%, 20% to 60%, or 25% to 55%.

The spring constant (Kz) of the wire 133A in the thickness direction is larger than the spring constant (Kxy) of the wire 133A in the width direction. Therefore, while the stiffness of the wire 133A hindering the movement of the wiring portion 3A is suppressed in the width direction, the stiffness of the wire 133A can increase the stiffness of the wiring portion 3A in the thickness direction.

A ratio (Kz/Kxy) of the spring constant (Kz) of the wire 133A in the thickness direction to the spring constant (Kxy) of the wire 133A in the width direction is preferably higher.

As the ratio (Kz/Kxy) is higher, the stiffness of the wiring portion in the thickness direction can be increased so as not to hinder the movement of the wiring portion in the width direction.

The wire 133A has a first conductor layer 1331 and a second conductor layer 1332. In the present embodiment, the wire 133A consists of the first conductor layer 1331 and the second conductor layer 1332.

The first conductor layer 1331 is disposed on the first insulating layer 12 in the thickness direction. The first conductor layer 1331 is disposed in the central portion C of the wire 133A in the width direction. The first conductor layer 1331 has a rectangular shape in the cross-sectional view. As shown in FIG. 2, in the present embodiment, the first conductor layer 1331 is connected to the terminal 131A and the terminal 132A. The first conductor layer 1331 is made of the same metal as that of the first conductor layer 1311 of the terminal 131A.

As shown in FIG. 4, the first conductor layer 1331 has a first width W21. The first width W21 is smaller than the width W11 of the wire 133A. The first width W21 is, for example, 1 μm or more, preferably 5 μm or more. The first width W21 is, for example, 50 μm or less, preferably 30 μm or less.

The second conductor layer 1332 is disposed on the first insulating layer 12 in the thickness direction. The second conductor layer 1332 covers the first conductor layer 1331. The second conductor layer 1332 is made of the same metal as that of the second conductor layer 1312 of the terminal 131A.

The second conductor layer 1332 has a second width W22. When the wire 133A consists of the first conductor layer 1331 and the second conductor layer 1332, the second width W22 is the same as the width W11 of the wire 133A. The second width W22 is larger than the first width W21. The second width W22 is, for example, 3 μm or more, preferably 10 μm or more. The second width W22 is, for example, 100 μm or less, preferably 75 μm or less.

### 3. Method of Producing Wiring Circuit Board

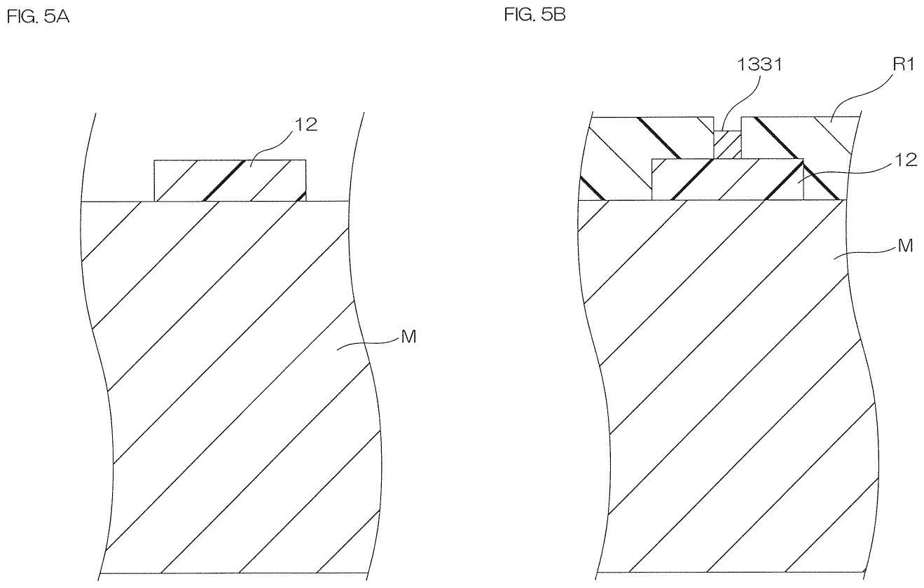

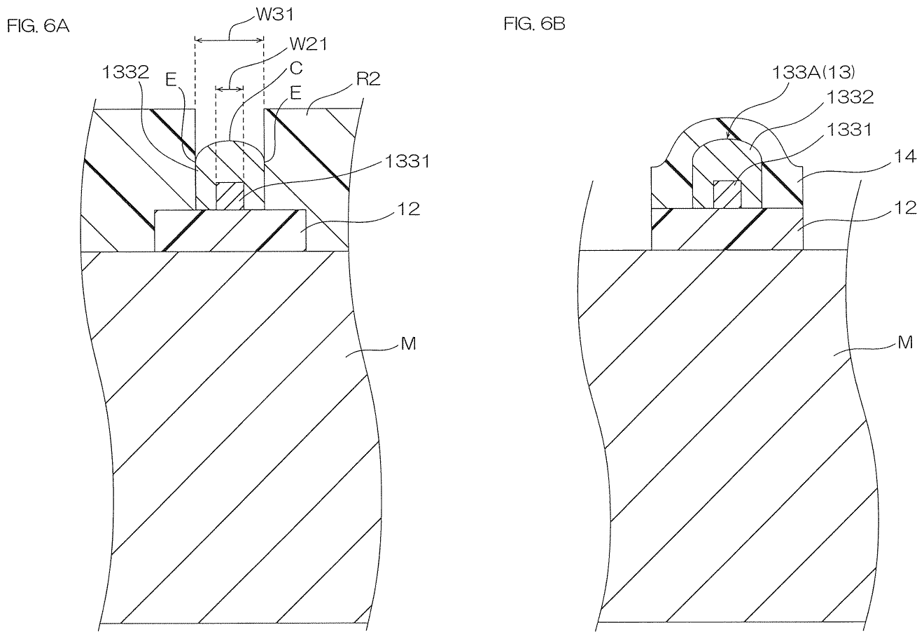

Next, referring to FIGS. 5A to 6B, a method of producing a wiring circuit board 1 is described.

The method of producing a wiring circuit board 1 includes a step of forming a first insulating layer (see FIG. 5A), a step of forming a first conductor layer (see FIG. 5B), a step of forming a second conductor layer (see FIG. 6A), a step of forming a second insulating layer (see FIG. 6B), and an etching step.

### (1) Step of Forming First Insulating Layer

As shown in FIG. 5A, in the step of forming a first insulating layer, a first insulating layer 12 is formed on a metal supporting layer 11. Specifically, as the material of the metal supporting layer 11, a roll of metal foil M is prepared. Next, a solution (varnish) of a photosensitive resin is applied onto the metal foil M drawn from the roll and dried. By the drying, a coating film of the photosensitive resin is formed on the metal foil M. Next, the coating film of the photosensitive resin is exposed to light and developed. By the development, the first insulating layer 12 is formed into a predetermined pattern on the metal foil.

(2) Step of Forming First Conductor layer

Next, as shown in FIG. 5B, in the step of forming a first conductor layer, the first conductor layer 1331 of each of the wires 133A and 133B and the first conductor layer 1311 of each of the terminals 131A, 132A, 131B, and 132B (see FIG. 1) are formed on the first insulating layer 12.

Specifically, first, a seed layer is formed on the surfaces of the first insulating layer 12 and the metal foil M. The seed layer is formed, for example, by sputtering. Examples of the material for the seed layer include, for example, chromium, copper, nickel, titanium, and the alloys thereof.

Next, a plating resist R1 is attached onto the first insulating layer 12 and metal foil M on both of which the seed layer has been formed. Then, while the parts in which the first conductor layer 1331 of each of the wires 133A and 133B, and the first conductor layer 1311 of each of the terminals 131A, 132A, 131B, and 132B are formed are shielded from light, the plating resist R1 is exposed to light.

Next, the exposed plating resist R1 is developed. Then, the plating resist R1 of the shielded parts is removed, and the seed layer is exposed in the parts in which the first conductor layer 1331 of each of the wires 133A and 133B, and the first conductor layer 1311 of each of the terminals 131A, 132A, 131B, and 132B are to be formed. On the other hand, the plating resist R1 of the exposed parts remains.

Next, the first conductor layer 1331 of each of the wires 133A and 133B, and the first conductor layer 1311 of each of the terminals 131A, 132A, 131B, and 132B are formed on the exposed seed layer by electroplating.

After the electroplating is completed, the plating resist R1 is peeled off.

### (3) Step of Forming Second Conductor Layer

Next, as shown in FIG. 6A, in the step of forming the second conductor layer, the second conductor layer 1332 of each of the wires 133A and 133B is formed on the first insulating layer 12, and the second conductor layer 1312 is formed on the first conductor layer 1311 of each of the terminals 131A, 132A, 131B, and 132B.

Specifically, first, a plating resist R2 is attached onto the first insulating layer 12, metal foil M, and first conductor layer 1331 on all of which a seed layer has been formed. Then, while the parts in which the second conductor layer 1332 of each of the wires 133A and 133B, and the second conductor layer 1312 of each of the terminals 131A, 132A, 131B, and 132B are formed are shielded from light, the plating resist R2 is exposed to light.

Next, the exposed plating resist R2 is developed. Then, the plating resist R2 of the shielded parts is removed, and the seed layer, the first conductor layer 1331, and the first conductor layer 1311 are exposed in the parts in which the second conductor layer 1332 of each of the wires 133A and 133B, and the second conductor layer 1312 of each of the terminals 131A, 132A, 131B, and 132B are to be formed. On the other hand, the plating resist R2 of the exposed parts remains.

In the developed plating resist R2, the width W31 of the part in which the second conductor layer 1332 is to be formed is larger than the width W21 of the first conductor layer 1331. Furthermore, the first conductor layer 1331 is disposed in a central portion of the part in which the second conductor layer 1332 is to be formed in the width direction.

Next, the second conductor layer 1332 is formed on the exposed seed layer and the first conductor layer 1331 by electrolytic plating, and the second conductor layer 1312 is formed on the first conductor layer 1311.

By forming the second conductor layer 1332 and the second conductor layer 1312, the above-described wires 133A and 133B and the terminals 131A, 132A, 131B, and 132B are completed. In the central portion C of each of the wires 133A and 133B in the width direction, the second conductor layer 1332 is laminated on the first conductor layer 1331. On the other hand, in both end portions E of each of the wires 133A and 133B in the width direction, the second conductor layer 1332 is formed on the first insulating layer 12. Therefore, as described above, the central portion C protrudes toward the one side in the thickness direction as compared with the end portion E by the thickness of the first conductor layer 1331 disposed therein.

After the electroplating is completed, the plating resist R2 is peeled off. Thereafter, the seed layer exposed by the peeling of the plating resist R2 is removed by etching.

### (4) Step of Forming Second Insulating Layer

Next, as shown in FIG. 6B, in the step of forming the second insulating layer, a second insulating layer 14 is formed on the first insulating layer 12 and the conductive pattern 13, in the same manner as the formation of the first insulating layer 12.

### (5) Etching Step

Next, in the etching step, by etching the metal foil M, a metal supporting layer 11 shown in FIG. 3 is formed.

In this manner, the wiring circuit board 1 shown in FIG. 1 is produced.

### 4. Operations and Effects

(1) According to the wiring circuit board 1, as shown in FIG. 4, the aspect ratio (T1/W1) of the wire supporting portion 112A is 2 or more. Therefore, the wire portion 3A can easily be moved in the width direction.

Then, the central portion C of the wire 133A protrudes toward the opposite side to the metal supporting layer 11 with respect to the first insulating layer 12, as compared with the end portion E, in the thickness direction.

Therefore, while an increase in the stiffness of the wire 133A in the width direction is suppressed, the stiffness of the wire 133A in the thickness direction can be increased.

Consequently, the stiffness of the wiring portion 3A in the thickness direction can be increased so as not to hinder the movement of the wiring portion 3A in the width direction.

(2) According to the wiring circuit board 1, as shown in FIG. 4, the aspect ratio (T11/W11) of the wire 133A is 2 or less.

Therefore, it is possible to suppress an excessive increase in the stiffness of the wiring portion 3A in the thickness direction.

(3) According to the wiring circuit board 1, as shown in FIG. 4, the protrusion rate of the central portion C is 10% or more.

Therefore, the stiffness of the wiring portion 3A in the thickness can reliably be increased.

(4) According to the wiring circuit board 1, as shown in FIG. 4, the wire 133A has the first conductor layer 1331 and the second conductor layer 1332. The first conductor layer 1331 is disposed in a central portion of the wire 133A in the width direction, and has a first width W21. The second conductor layer 1332 has a second width W22 larger than the first width W21, and covers the first conductor layer 1331.

Therefore, with a simple construction in which the second conductor layer 1332 covers the first conductor layer 1331, the wire 133A in which the central portion C protrudes as compared with the end portion E can be formed.

(5) The method of producing the wiring circuit board 1, as shown in FIGS. 5B and 6A, includes the step of forming a first conductor layer to form the first conductor layer 1331 on the first insulating layer 12 (see FIG. 5B) and the step of forming a second conductor layer to form the second conductor layer 1332 on the first insulating layer 12 (see FIG. 6A).

According to such a method, with a simple method in which the second conductor layer 1332 covers the first conductor layer 1331, the wire 133A in which the central portion C protrudes as compared with the end portion E can be formed.

### 5. Variations

Next, variations are described. In the variations, the same members as in the above-described embodiment are given the same reference numerals, and the descriptions thereof are omitted.

(1) The method of forming the wire 133A having an arched shape in the cross-sectional view is not limited. The wire 133A may be formed into an arched shape in the cross-sectional view by one electrolytic plating.

For example, by adjusting the ratio of the components (such as bright toner, leveler, polymer) in the plating solution so as to slow the plating growth near both ends in contact with the plating resist in the width direction as compared with the plating growth at the center away from the plating resist in the width direction, the wire 133A having a cross-sectional arched shape in which the central portion C protrudes as compared with the end portion E can be formed.

(2) The wire 133A may be formed by electroless plating.

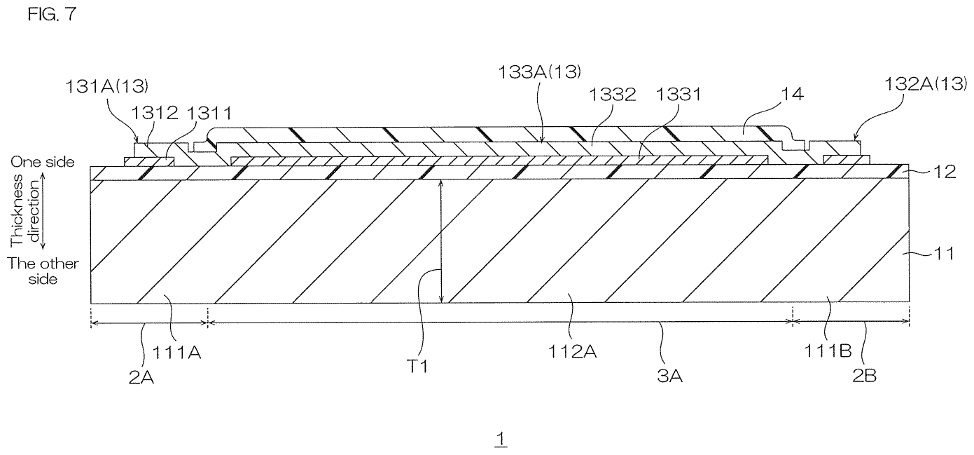

(3) As shown in FIG. 7, the first conductor layer 1331 of the wire 133A may be disposed away from the first conductor layer 1311 of the terminal 131A. In this case, the second conductor layer 1332 of the wire 133A may be connected to the second conductor layer 1312 of the terminal 131A.

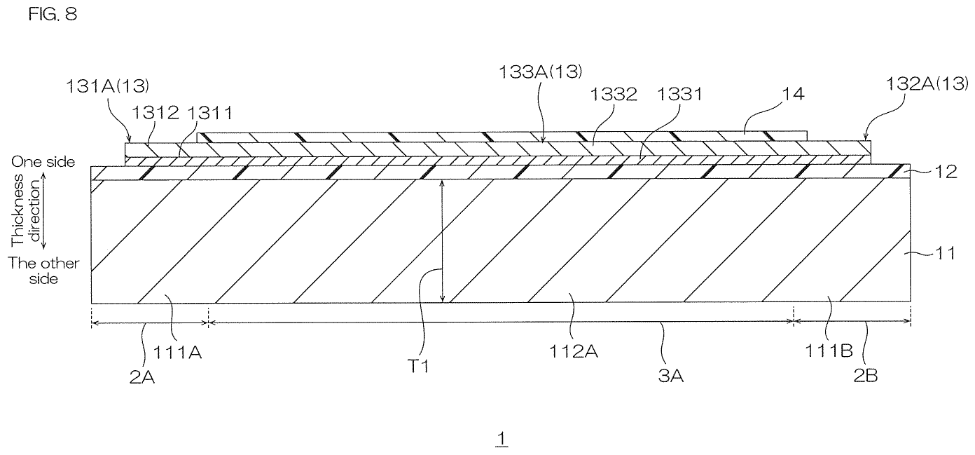

(4) As shown in FIG. 8, it may be that the first conductor layer 1331 of the wire 133A is connected to the first conductor layer 1311 of the terminal 131A, and the second conductor layer 1332 of the wire 133A is connected to the second conductor layer 1312 of the terminal 131A.

### EXAMPLES

Next, the present invention is described based on Example and Comparative Example. The present invention is not limited to Examples below. The specific numeral values used in the description below, such as physical property values and parameters, can be replaced with the corresponding physical property values and parameters in the above-described “DESCRIPTION OF THE EMBODIMENTS”, including the upper limit values (numeral values defined with “or less” or “less than”) or the lower limit values (numeral values defined with “or more” or “more than”).

The spring rate of a simulation model of the wire of each Example and Comparative example was calculated using a finite element method (Young's modulus: 130 GPa, a length of the wire: 4 mm).

The aspect ratio (T11/W11), protrusion rate of the central portion, spring constant (Kxy) in the width direction, spring constant (Kz) in the thickness direction, and the ratio (Kz/Kxy) of the spring constant in the thickness direction to the spring constant in the width direction of each simulation model are shown in Table 1.

### (1) Example 1

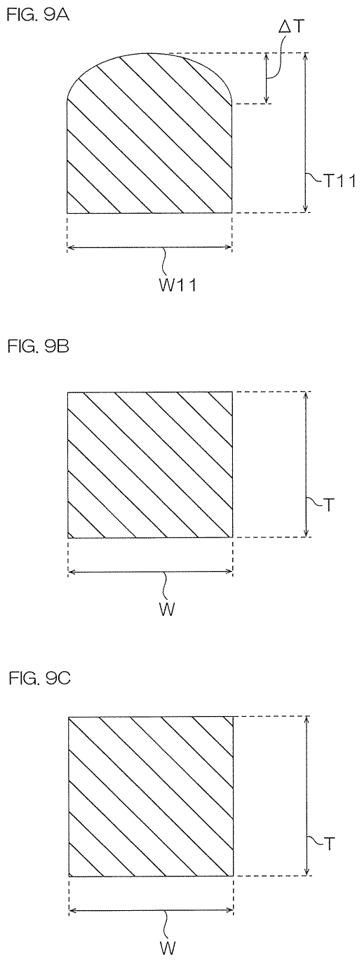

As shown in FIG. 9A, a simulation model of a wire having an arched shape in the cross-sectional view (width W11: 42 μm, thickness T11 of the central portion: 41 μm, difference ΔT between the thickness T11 of the central portion and the thickness T12 of the end portion: 13 μm) was produced.

### (2) Comparative Example 1

As shown in FIG. 9B, a simulation model of a wire having a rectangular shape in the cross-sectional view (width W: 42 μm, thickness T: 37.30 μm) was produced. The cross-sectional area of the simulation model of Comparative Example 1 was the same as that of the simulation model of Example 1.

### (3) Comparative Example 2

As shown in FIG. 9C, a simulation model of a wire having a rectangular shape in the cross-sectional view (width W: 42 μm, thickness T: 41 μm) was produced. The thickness T of the simulation model of Comparative Example 2 was the same as the thickness T11 of the central portion of the simulation model of Example 1.

### (4) Example 2

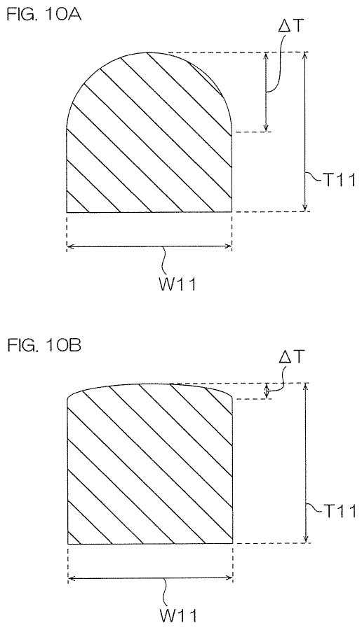

As shown in FIG. 10A, a simulation model of a wire having an arched shape in the cross-sectional view (width W11: 42 μm, thickness T11 of the central portion: 41 μm, difference ΔT between the thickness T11 of the central portion and the thickness T12 of the end portion: 20.5 μm) was produced.

### (5) Example 3

As shown in FIG. 10B, a simulation model of a wire having an arched shape in the cross-sectional view (width W11: 42 μm, thickness T11 of the central portion: 41 μm, difference ΔT between the thickness T11 of the central portion and the thickness T12 of the end portion: 4 μm) was produced.

### (6) Example 4

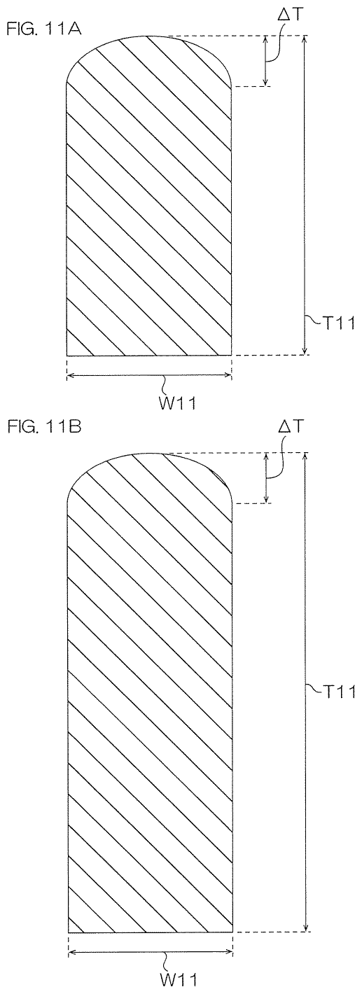

As shown in FIG. 11A, a simulation model of a wire having an arched shape in the cross-sectional view (width W11: 42 μm, thickness T11 of the central portion: 82 μm, difference ΔT between the thickness T11 of the central portion and the thickness T12 of the end portion: 13 μm) was produced.

### (7) Example 5

As shown in FIG. 11B, a simulation model of a wire having an arched shape in the cross-sectional view (width W11: 42 μm, thickness T11 of the central portion: 123 μm, differences ΔT between the thickness T11 of the central portion and the thickness T12 of the end: 13 μm) was produced.

TABLE 1

| | | | | | | Comp. | Comp. |
|---|---|---|---|---|---|---|---|
| | Example 1 | Example 2 | Example 3 | Example 4 | Example 5 | Ex. 1 | Ex. 2 |
| T11/W11 | 1.00 | 1.00 | 1.00 | 1.95 | 2.93 | 0.89 | 1.00 |
| Protrusion rate (%) | 31 | 50 | 10 | 16 | 11 | 0 | 0 |
| Kxy (mN/mm) | 68.3 | 64.6 | 77.2 | 147.6 | 223.5 | 74.6 | 81.8 |
| Kz (mN/mm) | 276.8 | 270.5 | 293.6 | 582.4 | 879.2 | 275.8 | 303.3 |
| Kz/Kxy | 4.05 | 4.18 | 3.80 | 3.95 | 3.93 | 3.70 | 3.71 |

While the illustrative embodiments of the present invention are provided in the above description, such is for illustrative purpose only and it is not to be construed as limiting in any manner. Modification and variation of the present invention that will be obvious to those skilled in the art is to be covered by the following claims.

### INDUSTRIAL APPLICABILITY

The wiring circuit board of the present invention can be used for the connection to an electronic component.

### DESCRIPTION OF REFERENCE NUMERALS

1 wiring circuit board
2A terminal disposition portion
3A wiring portion
11 metal supporting layer
W1 width of the wire supporting portion (width of the wire supporting portion of the wiring portion)
T1 thickness of the wire supporting portion (thickness of the wire supporting portion of the wiring portion)
12 first insulating layer (an example of an insulating layer)
13 conductive pattern
131A terminal
133A wire
C central portion of the wire in the width direction
E end portion of the wire in the width direction
W11 width of the wire
T11 thickness of the central portion
1331 first conductor layer
W21 first width
1332 second conductor layer
W22 second width

1. A wiring circuit board having a terminal disposition portion in which a terminal is disposed, and a wiring portion in which a wire connected to the terminal is disposed, the wiring circuit board comprising:
a metal supporting layer;
an insulating layer disposed on the metal supporting layer in a thickness direction of the metal supporting layer; and
a conductive pattern disposed on the insulating layer in the thickness direction, and the conductive pattern having the terminal and the wire,
wherein a ratio of a thickness of the metal supporting layer of the wiring portion to a width of the metal supporting layer of the wiring portion is 2 or more,
wherein the wire has a central portion and an end portion in a width direction of the wiring portion, and
wherein the central portion protrudes toward an opposite side to the metal supporting layer with respect to the insulating layer in the thickness direction as compared with the end portion.

2. The wiring circuit board according to claim 1,
wherein a ratio of a thickness of the central portion to a width of the wire is 2 or less.

3. The wiring circuit board according to claim 1,
wherein a difference between the thickness of the central portion and a thickness of the end portion is 10% or more of the thickness of the central portion.

4. The wiring circuit board according to claim 1,
wherein the wire including:
a first conductor layer disposed on the insulating layer in the thickness direction, the first conductor layer disposed in the central portion of the wire in the width direction, and the first conductor layer having a first width; and
a second conductor layer disposed on the insulating layer in the thickness direction, the second conductor layer having a second width larger than the first width, and the second conductor layer covering the first conductor layer.

5. A method of producing the wiring circuit board according to claim 4, the method comprising:
an insulating layer formation step of forming the insulating layer on the metal supporting layer,
a first conductor layer formation step of forming the first conductor layer on the insulating layer; and
a second conductor layer formation step of forming the second conductor layer on the insulating layer.
